(19) United States
(12) Patent Application Publication
(10) Pub. No.: US 2010/0055022 A1
(43) Pub. Date: Mar. 4, 2010

(54) DIAMOND IDENTIFIER

(75) Inventors: Bryant Linares, Sherborn, MA (US); Robert C. Linares, Sherborn, MA (US); Patrick J. Doering, Holliston, MA (US)

Correspondence Address: SCHWEGMAN, LUNDBERG & WOESSNER, P.A., P.O. BOX 2938, MINNEAPOLIS, MN, 55402, US

(73) Assignee: Apollo Diamond Gemstone Corporation, Framingham, MA (US)

(21) Appl. No.: 12/463,121

(22) Filed: May 8, 2009

Related U.S. Application Data
(60) Provisional application No. 61/051,878, filed on May 9, 2008.

(51) Int. Cl. C01B 31/06; G01N 21/87; G01N 21/95; C23C 16/27

(52) U.S. Cl. 423/446; 356/30; 427/8

(57) ABSTRACT

Diamonds are embedded with one or more layers representative of an identifier. The identifier may include encoding in the form of defects created in one or more layers in a recognizable pattern, such as a bar code, characters or symbols. In some embodiments, a single crystal CVD diamond is formed with layers of varying thickness to provide the encoding. A system includes a radiation source to provide short wavelength light. A holder positions a gemstone to receive the light. A detector is positioned to receive fluorescent light from the gemstone when the gemstone is a CVD grown gemstone, and a pattern identifier correlates a detected pattern of defects to unique identification information.

### CROSS-REFERENCE TO RELATED APPLICATIONS

This application claims priority to U.S. Provisional Application Ser. No. 61/051,878, filed May 9, 2008, the entire disclosure of which is incorporated by reference herein.

### BACKGROUND

A diamond may be inscribed with an identifier to help uniquely identify it. The inscribing may be done physically to the diamond using a laser or other tool to create a visible identifying mark, which may be alphanumeric in some examples. The mark may be provided on a girdle of a cut diamond, on a facet, or even on the table of the diamond if small enough so that it is not visible to the human eye or does not otherwise affect the appearance of the diamond. Some surface markings may be removed by further polishing of the diamond.

### BRIEF DESCRIPTION OF THE DRAWINGS

FIG. 1A is a diagram of a mask used to create a desired pattern of implanted defects in a diamond according to an example embodiment.

FIG. 1B is a block diagram cross section of a multiple layer CVD grown diamond according to an example embodiment.

FIG. 2 is a diagram illustrating a method of forming defects in a diamond according to an example embodiment.

FIG. 3 is a block diagram of a system for reading defects in diamond to view a pattern of defects in a diamond according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that changes may be made without departing from the scope of the present invention. The following description of example embodiments is, therefore, not to be taken in a limited sense, and the scope of the present invention is defined by the appended claims.

Defects can be used to uniquely identify diamonds in various embodiments. In some embodiments, nitrogen vacancy centers (N-V centers) may be formed in diamond, such as chemical vapor deposition (CVD) grown diamond in one or more layers, and detected to uniquely identify the diamond. The defects may be formed with other impurities in further embodiments, such as nickel, hydrogen or other impurities. The implanted vacancy centers may be formed in a predetermined pattern that may be unique to each diamond if desired, or may be formed at random. The patterns may be read by observing emissions in response to low frequency light, and cataloged in a database to uniquely identify each diamond produced. Further, stacks of defect layers with controlled variation of defect density, layer thickness, and number of layers may be formed during the CVD growth process. In further embodiments, defects in a CVD grown diamond may be formed by deposition or evaporation of a layer of material, such as platinum or other metals. Such layers may also be patterned. Diamond growth may be resumed after each defect layer is formed, and grows up and over the formed layer.

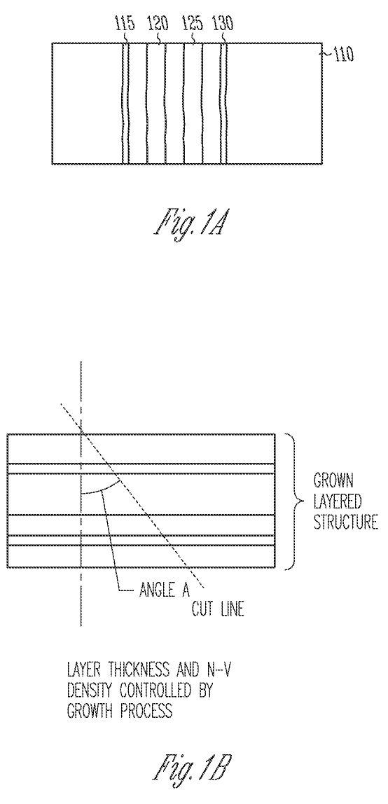

A mask 110 in FIG. 1A is illustrated and may be used to create a desired pattern of implanted ions. In one example, a bar code like pattern of bars 115, 120, 125, 130 may be used, wherein the width and spacing of the bars carries information that may be scanned when the diamond is illuminated with low wavelength light, fed into an image recognition program or other functionality akin to bar code readers, to provide a unique identification of the diamond. Newer bar code type patterns may also be used in further embodiments.

In one embodiment, the mask 110 may contain many more bars, or may contain different types of patterns, including alphanumeric and other characters used to form a unique ID. When forming a plate of diamond, from which chips or gemstones may be cut, each such chip or gemstone may have a corresponding mask with a different unique ID. A single mask may be used in one embodiment, with different sub masks corresponding to each chip or gemstone to be implanted. In further embodiments, the diamond may be grown directly on various industrial products such as scalpels, electrodes, and other products, with the resulting patterns forming an ID for the product.

In some embodiments, at least a portion of the ID may be the same and represent a desired characteristic of the diamond, such as identifying it as a CVD grown stone, a CVD grown stone from a particular manufacturer, a serial number, or any other type of information desired.

In another embodiment, a diamond crystal can be grown with one or more regions containing stacks of layers with varying defect density, thickness, and number of layers as illustrated at 150 in FIG. 1B. Such structures can be formed during the CVD growth process by selectively adding impurities (such as nitrogen or boron) at controlled levels and for controlled times to create the desired layer. The layer surface cross section can be further modified by cutting across the layer at a controlled angle with the angle of the cut controlling the layer thickness as seen at the cross sectional cut. In addition, the defect structure in the layer(s) can be controllably modified after growth by subjecting the crystal to appropriate heat treatments. Such layer structures can form unique “bar codes” in the diamond crystal. Layers produced in this manner can be made to be detectable through various luminescence techniques (such as photoluminescence and cathodoluminscence).

The diamond containing the ID may be cut and polished into a gemstone or baguette or other form of stone, and may be embedded or attached to a larger item to serve as a unique ID for the larger item, such as a larger piece of jewelry or a watch, or other item.

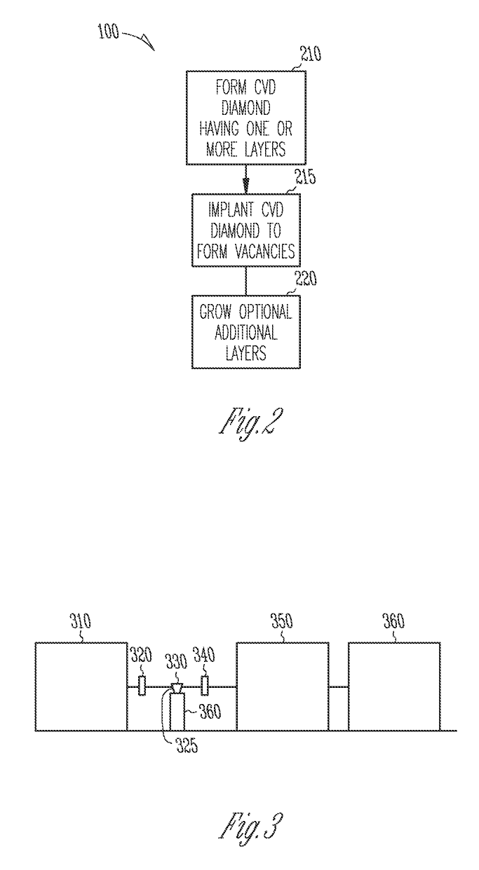

FIG. 2 illustrates a process 200 for forming a CVD diamond having an ID based on defects. At 210, a CVD diamond may be formed having one or more layers. The layers may have different doping levels and be of different thicknesses. At 215, the CVD diamond formed is implanted to form defects. At 220, additional layers of diamond may be formed on top of the implanted layer.

As indicated above, the implantation may be done with a mask, or without a mask, resulting in different patterns of defects being formed in the diamond. In place of a mask, predetermined patterns of defects may be formed by implanting using a focused beam controlled to form the patterns. The depth of the implant may be used in further embodiments to provide an additional degree of freedom to obtain further unique patterns.

In some cases, the implanted crystal may be subjected to heat treatments in order to controllably modify the nature of the defects formed. Heat may be used to adjust the defect density. In one embodiment, annealing is performed by using heat to diffuse vacancies. Temperatures of about 700 to 1000° C. may be used to diffuse the vacancies. The vacancies may diffuse to form nitrogen vacancies in one embodiment. In further embodiments, higher heats, such as temperatures in the 1700 to 2000° C. level may be used to destroy nitrogen vacancies. Times for such heat treatments may range from 30 minutes to an hour in some embodiments. Shorter and longer times may be used if they provide desired coloration. In some embodiments, the heat treatments/annealing may be done in a vacuum, an inert atmosphere, or in a hydrogen atmosphere.

In one embodiment, implantation without a mask may be used to create a randomized pattern of defects. The defects may be scanned and entered into a database and associated with a unique ID. Much information may be associated with unique IDs, whether corresponding to patterned defects or random defects. The information may include manufacturing data such as serial number, date of manufacture, one or more parameters associated with the manufacturing process, and even ownership information in some embodiments. The implantation may be done while the diamond is still part of the plate of CVD diamond being formed, or may be done after the diamond has been separated from the plate and finished.

In some embodiments, implanting may be done on more than one level or layer of the CVD diamond being formed. Such multilayer implantation provides additional variations to form unique IDs. In one embodiment, the ID may be formed in a central part of a gemstone to make it difficult to remove the ID by polishing or cutting layers off the stone. In further embodiments, the diamond may be a single crystal CVD formed diamond. In still further embodiments, the implantation may be done on high pressure high temperature formed diamonds or on natural diamonds. The implantation depth may be selected to either minimize damage to the diamond, or to ensure that it is sufficiently deep in the diamond to minimize the risk of removal by polishing or other means.

In one embodiment, an entire layer within a plate of diamond being formed via CVD, such as a single crystal CVD diamond plate, may be encoded with identification data comprising defects in predetermined patterns. Such information may be representative of manufacturing data for the plate, and may be shared across all gemstones produced from the plate. Each gemstone may be personalized with an additional encoded layer before or after cutting from the plate. In still further embodiments, some layers of the plate itself may be varied in thickness between plates to provide encoding in the plate as a function of layer type and thickness.

A system 300 in FIG. 3 may be used to identify IDs formed with defects in diamond. System 300 may be formed in a size that is compatible for deployment in a jewelry retail store and be operated by relatively unskilled personnel. System 300 may utilize the presence of an N-V center or other vacancy in further embodiments in a diamond. At 310, a radiation source provides short wavelength light. The short wavelength light may be provided by a green or blue laser, such as a commercially available semiconductor laser which emits at 405 or 532 nm and a fiber optic delivery system or lens 320 may be used to provide short wavelength radiation to a holder 325 to position a table of a gemstone 330 at a predetermined distance from the laser light. The laser in one embodiment is highly focused on the crystal surface of the gemstone. A filter(s) (or spectrometer) 340 may be used to separate the laser light from the PL light (photo-luminescence).

The presence of N-V centers would result in emission bands centered at about 575 and/or 637 nm, and the filters can be used to allow detection of these wavelengths. A detector 350 may be positioned to receive and detect the PL light. In one embodiment, a thermoelectric cooler 360 may be used to cool the gemstone. The cooler 360 may be integrated with the holder 320 in one embodiment. Detector 350 may contain suitable electronics and metering to indicate the nature and type of the diamond from the detected PL light.

Detector 350 may include a microscope for microscopic examination to identify the defects. The microscope may provide an output that is digitized, and representative of the vacancy pattern. This digitized representation may be fed to a pattern identifier 360, which may include pattern recognition software for identifying alphanumeric characters, bar codes, symbols and other information encoded into the vacancy pattern. Even random patterns may be digitally quantized to enable comparison to stored random patterns. The recognized patterns may be used to access a database of IDs, or the patterns themselves may be mathematically converted to corresponding unique IDs to allow identification of individual stones.

In further embodiments, filters or an inexpensive spectrometer may be used to separate wavelengths to ensure that the laser light and the PL light are separated. A suitable covering may be used to eliminate stray room light from entering the detector and laser light from straying to the outside. Safety interlocks may be provided to shut down the laser in the event the cover is removed. Holder 325 may be made large enough to hold several sizes of stones. Control circuitry and sensors may be included to indicate a pass, fail, or further inspection notice for the tester.

Some embodiments may be made fairly inexpensive and have a fairly small footprint, and be easy to operate, making them suitable for use and operation by a store clerk in a retail store.

In still further embodiments, a patterned layer or layers of platinum or other metal may be deposited or evaporated onto a CVD diamond. Such patterns are effectively a defect in the CVD diamond. The pattern of the one or more layers may also have the shapes as described above to represent a unique ID. Such layers may be formed between CVD diamond growth periods. After a layer is formed, further CVD diamond may be grown up and over such patterned layers.

In one embodiment, one or more patterned layers of defects may be used to provide a marker for a plate of diamond being grown that may be shared between all the gemstones or other products that may be later derived from the plate of diamond. As the other products to be derived are identified, either prior to the initial growth, during or after, other layers may be formed and patterned that are local to such products. Thus, the resulting products may have a plate marker or ID, along with a separate layer or layers that form a specific product ID or marker. Implants of patterned layer of dopants may also be created after completion of the growth of the plate of diamond, or even after products have been separated from the plate of diamond in further embodiments.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

What is claimed is:

1. A system comprising:
a radiation source to provide short wavelength light;
a holder to position a table of a gemstone to receive the light;
a detector positioned to receive fluorescent light from a pattern of defects in the gemstone; and
a pattern identifier that determines an identifier from the detected pattern of defects in the gemstone.

2. The system of claim 1 wherein the defects are N-V centers.

3. The system of claim 2 wherein the defects are randomized between gemstones.

4. The system of claim 2 wherein the defects form a predetermined pattern in accordance with an ion implantation mask.

5. A system of claim 2 wherein the defects are formed during CVD growth to create a predetermined layered structure with controlled defect density, thickness, and number of layers.

6. The system of claim 1 and further comprising means for cooling the gemstone.

7. The system of claim 1 wherein the filter provides emitted light from the gemstone to the detector when the gemstone is a CVD grown gemstone.

8. The system of claim 1 wherein the radiation source comprises a short wavelength laser.

9. The system of claim 6 wherein the detection optics and sensors are tailored to detect light with wavelength(s) near 575 and/or 637 nm.

10. A method comprising:
forming CVD diamond having multiple layers of diamond;
forming a pattern of defects in the CVD diamond; and
identifying the pattern of defects implanted in the CVD diamond.

11. The method of claim 10 wherein the CVD diamond comprises a single crystal CVD diamond.

12. The method of claim 10 wherein the defects comprise N-V centers.

13. The method of claim 10 wherein the defects comprise Nickel defects.

14. The method of claim 10 wherein the defects comprise a patterned metal layer on top of a CVD diamond layer with CVD diamond grown over such defects.

15. The method of claim 10 wherein the pattern of defects comprises a bar code.

16. The method of claim 10 wherein the pattern of defects comprises alphanumeric characters.

17. The method of claim 10 wherein the pattern of defects is random.

18. A diamond comprising:
multiple layers of CVD grown single crystal diamond;
a layer of the diamond further comprising a unique pattern of defects corresponding to an identifier of the CVD grown single crystal diamond.

19. The diamond of claim 18 wherein the defects comprise N-V centers.

20. The diamond of claim 18 wherein the unique pattern of defects is in the form of a bar code.

21. The diamond of claim 18 wherein the unique pattern of defects comprises alphanumeric characters.

22. The diamond of claim 18 and further comprising an additional layer encoded with a pattern of defects.

23. A diamond comprising:
multiple layers of single crystal diamond, wherein the layers comprise a unique pattern of layer thicknesses representative of a unique identifier for the diamond.

24. A diamond comprising:
multiple layers of single crystal diamond, wherein at least one layer comprises a pattern of defects representative of a unique identifier for the diamond.
